(19) United States
(12) Patent Application Publication
(10) Pub. No.: US 2026/0150680 A1
(43) Pub. Date: May 28, 2026

(54) MICROFLUIDIC COOLING OF GALLIUM NITRIDE OR OTHER GROUP III-V MATERIAL-ON-SILICON DEVICES USING BACKSIDE CAVITY APPROACH

(71) Applicant: Raytheon Company, Tewksbury, MA (US)

(72) Inventors: Jon Sigurdson, Santa Barbara, CA (US); Eric R. Miller, Orcutt, CA (US); Jason G. Milne, El Segundo, CA (US); Jason M. Kehl, Inglewood, CA (US); Lovelace J. Soirez, Andover, MA (US); Jeffrey R. Laroche, Austin, TX (US); Aaron George, San Diego, CA (US)

(21) Appl. No.: 18/957,459

(22) Filed: Nov. 22, 2024

(51) Int. Cl. H01L 23/46

(52) U.S. Cl. CPC H10W 40/40

(57) ABSTRACT

An apparatus includes a silicon substrate and a Group III-V layer over a front-side of the silicon substrate. The Group III-V layer includes at least one Group III-V material and one or more circuit components. The apparatus also includes a silicon wafer attached to a back-side of the silicon substrate. The silicon substrate includes a cavity formed in the back-side of the silicon substrate. The cavity extends partially through the silicon substrate and adjacent to a region of the Group III-V layer containing at least one of the one or more circuit components. The silicon wafer includes one or more fluid ports in fluid communication with the cavity. The cavity and the one or more fluid ports form a cooling channel configured to provide a flow of cooling fluid through the silicon wafer and silicon substrate.

### TECHNICAL FIELD

This disclosure relates generally to semiconductor devices. More specifically, this disclosure relates to microfluidic cooling of gallium nitride (GaN) or other Group III-V material-on-silicon (Si) devices using a backside cavity approach.

### BACKGROUND

Gallium nitride (GaN) semiconductor devices and other semiconductor devices formed using Group III-V materials often represent high-powered devices that can generate significant amounts of thermal energy. While Group III-V-based semiconductor devices are typically able to withstand higher temperatures than conventional silicon (Si)-based semiconductor devices, Group III-V-based semiconductor devices can still be limited by the thermal energy they produce. As a result, the performance of Group III-V-based semiconductor devices may suffer if adequate thermal management is not provided.

### SUMMARY

This disclosure relates to microfluidic cooling of gallium nitride (GaN) or other Group III-V material-on-silicon (Si) devices using a backside cavity approach.

In a first embodiment, an apparatus may include a silicon substrate and a Group III-V layer over a front-side of the silicon substrate. The Group III-V layer may include at least one Group III-V material and one or more circuit components. The apparatus may also include a silicon wafer attached to a back-side of the silicon substrate. The silicon substrate may include a cavity formed in the back-side of the silicon substrate. The cavity may extend partially through the silicon substrate and adjacent to a region of the Group III-V layer containing at least one of the one or more circuit components. The silicon wafer may include one or more fluid ports in fluid communication with the cavity. The cavity and the one or more fluid ports may form a cooling channel configured to provide a flow of cooling fluid through the silicon wafer and the silicon substrate.

Any single one or any combination of the following features may be used with the first embodiment. The apparatus may include a back end of line (BEOL) layer over the Group III-V layer, and the BEOL layer may provide electrical connection to the one or more circuit components. The apparatus may include a bonding layer configured to attach the silicon wafer to the silicon substrate. The apparatus may include a dielectric layer over a back-side of the silicon wafer. The apparatus may include a metal deposited around each opening of the one or more fluid ports. The apparatus may include one or more conductive vias extending at least partially through the silicon substrate and the silicon wafer. At least one via in the silicon substrate may be electrically connected to at least one via in the silicon wafer. The silicon substrate, the Group III-V layer, and the silicon wafer may form one layer of a multi-layer structure. The at least one Group III-V material may include gallium nitride.

In a second embodiment, a method may include obtaining a semiconductor structure having a silicon substrate and a Group III-V layer over a front-side of the silicon substrate. The Group III-V layer may include at least one Group III-V material and one or more circuit components. The method may also include forming a cavity in a back-side of the silicon substrate. The cavity may extend partially through the silicon substrate and adjacent to a region of the Group III-V layer containing at least one of the one or more circuit components. The method may further include attaching a silicon wafer to the back-side of the silicon substrate. In addition, the method may include forming one or more fluid ports through the silicon wafer and in fluid communication with the cavity. The cavity and the one or more fluid ports may form a cooling channel configured to provide a flow of cooling fluid through the silicon wafer and the silicon substrate.

Any single one or any combination of the following features may be used with the second embodiment. The semiconductor structure may include a first back-side stress compensation layer over the back-side of the silicon substrate. The method may include, prior to forming the cavity in the back-side of the silicon substrate, attaching an additional silicon wafer to a passivation layer over the front-side of the silicon substrate, removing the first back-side stress compensation layer, and forming a front-side stress compensation layer over the additional silicon wafer. The method may include, after forming the cavity in the back-side of the silicon substrate, removing the front-side stress compensation layer and forming a second back-side stress compensation layer over a back-side of the silicon wafer. Each fluid port may be formed through the second back-side stress compensation layer. The semiconductor structure may include a BEOL layer over the Group III-V layer, and the BEOL layer may provide electrical connection to the one or more circuit components. The method may include, after forming the one or more fluid ports through the silicon wafer, etching the BEOL layer to expose conductive pads of the BEOL layer. Attaching the silicon wafer to the back-side of the silicon substrate may include using a bonding layer to attach the silicon wafer to the silicon substrate. The method may include depositing a metal around each opening of the one or more fluid ports. The method may include forming one or more conductive vias extending at least partially through the silicon substrate and the silicon wafer. The at least one Group III-V material may include gallium nitride.

In a third embodiment, a method may include obtaining an electronic device having a silicon substrate, a Group III-V layer over a front-side of the silicon substrate (the Group III-V layer including at least one Group III-V material and one or more circuit components), and a silicon wafer attached to a back-side of the silicon substrate. The silicon substrate may include a cavity formed in the back-side of the silicon substrate. The cavity may extend partially through the silicon substrate and adjacent to a region of the Group III-V layer containing at least one of the one or more circuit components. The silicon wafer may include one or more fluid ports in fluid communication with the cavity. The method may also include passing a cooling fluid through the one or more fluid ports into and out of the cavity.

Any single one or any combination of the following features may be used with the third embodiment. The one or more circuit components may include at least one high-electron-mobility transistor. The at least one Group III-V material may include gallium nitride.

Other technical features may be readily apparent to one skilled in the art from the following figures, descriptions, and claims.

### BRIEF DESCRIPTION OF THE DRAWINGS

For a more complete understanding of this disclosure, reference is made to the following description, taken in conjunction with the accompanying drawings, in which:

FIG. 1 illustrates an example Group III-V material-on-silicon device supporting microfluidic cooling using a backside cavity approach according to this disclosure;

FIG. 2 illustrates an example process for forming a Group III-V material-on-silicon device supporting microfluidic cooling using a backside cavity approach according to this disclosure;

FIGS. 3A through 3I illustrate example structures that may be formed during the process of FIG. 2 according to this disclosure;

FIG. 4 illustrates an example method for forming a Group III-V material-on-silicon device supporting microfluidic cooling using a backside cavity approach according to this disclosure; and

FIGS. 5 through 7 illustrate example structures that integrate Group III-V material-on-silicon devices supporting microfluidic cooling using a backside cavity approach according to this disclosure.

### DETAILED DESCRIPTION

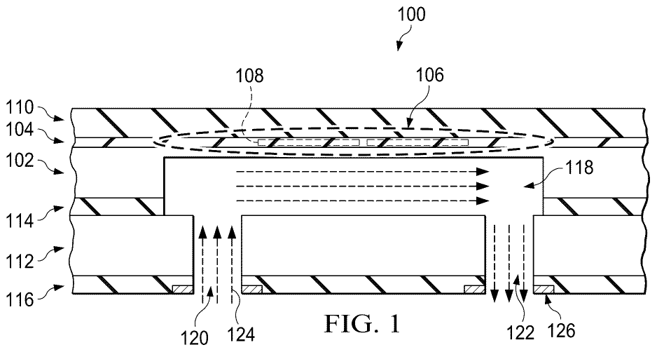

FIGS. 1 through 7, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As noted above, gallium nitride (GaN) semiconductor devices and other semiconductor devices formed using Group III-V materials often represent high-powered devices that can generate significant amounts of thermal energy. While Group III-V-based semiconductor devices are typically able to withstand higher temperatures than conventional silicon (Si)-based semiconductor devices, Group III-V-based semiconductor devices can still be limited by the thermal energy they produce. As a result, the performance of Group III-V-based semiconductor devices may suffer if adequate thermal management is not provided.

One approach for providing thermal management of semiconductor devices involves the use of microfluidic cooling. Microfluidic cooling typically involves forming small cooling channels near semiconductor devices so that fluid flowing through the cooling channels can remove thermal energy from or near the semiconductor devices. Adding microfluidic cooling to semiconductor devices can allow for expanded use of the semiconductor devices, such as by allowing for increased device density, improved device performance, and improved device reliability.

Unfortunately, microfluidic cooling of Group III-V-based semiconductor devices is generally much more difficult to provide compared to conventional silicon-based semiconductor devices. For example, gallium nitride-on-silicon and other Group III-V material-on-silicon devices represent semiconductor devices in which gallium nitride or other Group III-V material(s) can be formed over a silicon substrate. Lattice mismatches between the gallium nitride or other Group III-V material(s) and the silicon substrate can cause various problems with respect to the formation of cooling channels for microfluidic cooling. Among other things, these lattice mismatches can cause Group III-V material-on-silicon wafers to be highly stressed, very fragile, and prone to breaking. Because of this, it is generally not simple or even possible to form cooling channels in Group III-V material-on-silicon wafers using known techniques, and damage to the Group III-V material-on-silicon wafers can be a common result.

This disclosure provides various structures and techniques involving microfluidic cooling of gallium nitride or other Group III-V material-on-silicon devices. Among other things, this disclosure provides processes for forming cooling channels to support microfluidic cooling of gallium nitride or other Group III-V material-on-silicon devices. In some cases, the processes can be used to create cavities adjacent to or otherwise near Group III-V material-on-silicon devices from the back-side of a silicon substrate and to create fluid ports that allow fluid to access the cavities, thereby forming cooling channels. The processes can also include various operations that surmount the fragility of Group III-V material-on-silicon devices and other associated process challenges, such as by providing precise stress management of various layers of materials.

FIG. 1 illustrates an example Group III-V material-on-silicon device 100 supporting microfluidic cooling using a backside cavity approach according to this disclosure. As shown in FIG. 1, the device 100 includes a silicon substrate 102 and a Group III-V layer 104 formed on or over the silicon substrate 102. The silicon substrate 102 represents any suitable structure formed of silicon that can be used to carry or support other components of the device 100. The silicon substrate 102 may be formed in any suitable manner and using any suitable form of silicon. In some embodiments, for instance, the silicon substrate 102 may represent a silicon wafer, such as a wafer formed using <111> silicon.

The Group III-V layer 104 represents at least one layer that includes gallium nitride (GaN) or other Group III-V material(s). The Group III-V layer 104 may be formed in any suitable manner (such as epitaxially) and have any suitable thickness(es). A region 106 of the Group III-V layer 104 represents an area in which at least one Group III-V semiconductor device 108 is located. The at least one Group III-V semiconductor device 108 may represent any suitable semiconductor device, such as at least one Group III-V transistor (like a high-electron-mobility transistor or “HEMT” device). The presence of the Group III-V semiconductor device(s) 108 in the region 106 generally results in the production of thermal energy in and around the region 106. Removal of at least some of the thermal energy from the region 106 may be necessary or desirable in order to support expected or desired operation of the Group III-V semiconductor device(s) 108 in the region 106.

Note that while two Group III-V semiconductor devices 108 are shown in the region 106 in this example, the region 106 may include any other suitable number of Group III-V semiconductor devices 108. Also, the Group III-V layer 104 may include or support other or additional type(s) of semiconductor devices or other integrated circuit components within or outside of the region 106. For instance, one or more resistors (such as tantalum nitride (TaN) resistors) may be formed in or over the Group III-V layer 104.

A back end of line (BEOL) layer 110 is formed over the front-side of the Group III-V layer 104. The BEOL layer 110 generally represents an interconnect layer or other layer(s) of material(s) deposited on or otherwise positioned over the Group III-V layer 104. Among other things, the BEOL layer 110 can provide electrical connection to the Group III-V semiconductor devices 108 and other integrated circuit components of the Group III-V layer 104. In some embodiments, for example, the BEOL layer 110 may include electrically-conductive pathways coupling the Group III-V semiconductor device(s) 108 in the region 106 to other components of a larger device. The BEOL layer 110 may be formed using any suitable material(s) (such as copper or other conductive traces) and in any suitable manner.

The back-side of the silicon substrate 102 in FIG. 1 is attached to a wafer 112 using a bonding layer 114. The wafer 112 represents any suitable structure that can be bonded or otherwise attached to the back-side of the silicon substrate 102 in order to support subsequent formation of one or more cooling channels. In some embodiments, for example, the wafer 112 represents a silicon handle wafer or thin silicon wafer. The bonding layer 114 represents at least one layer of material(s) that can be used to bond or otherwise attach the wafer 112 to the silicon substrate 102. In some embodiments, for instance, the bonding layer 114 represents an oxide layer. At least one dielectric layer 116 may be formed over the back-side of the wafer 112. The dielectric layer 116 may be formed using any suitable dielectric material(s), such as silicon dioxide (SiO₂). The dielectric layer 116 may also be formed in any suitable manner and may have any suitable thickness(es).

In order to support cooling of the Group III-V semiconductor device(s) 108 or other components in the region 106, a cavity 118 is formed in the wafer 112 adjacent to or otherwise near the region 106, and one or more fluid ports 120 and 122 are formed through the wafer 112 and into the cavity 118. In some embodiments, one of the fluid ports 120 and 122 may be used to provide a cooling fluid 124 into the cavity 118, and another of the fluid ports 120 and 122 may be used to receive the cooling fluid 124 from the cavity 118. A cooling channel that includes the cavity 118 and the one or more fluid ports 120 and 122 can be created, where the cooling channel can be used to remove thermal energy generated by the Group III-V semiconductor device(s) 108 or other components in the region 106. For example, a flow of cooling fluid through each cooling channel can be used to remove thermal energy generated by at least one Group III-V semiconductor device 108 or other circuit component(s) in the region 106. For the reasons discussed above, the overall structure shown in FIG. 1 can be relatively fragile, and this fragility may be due (among other things) to lattice mismatches between the silicon substrate 102 and the Group III-V layer 104. The cooling channel shown here may be formed using the process described below, where the process can account for the fragility of the overall structure.

In some embodiments, a metal 126 may optionally be deposited or otherwise formed around the opening of each fluid port 120 and 122. The metal 126 may be used to support or improve the formation of seals between the one or more fluid ports 120 and 122 and one or more external fluid pathways that can transport the cooling fluid 124 to and from the device 100. For example, the metal 126 may be added onto the dielectric layer 116 to support an improved connection seal between the fluid port(s) 120 and 122 and the external fluid pathway(s). The metal 126 may include any suitable metal(s) that can be used to facilitate formation of a seal, such as copper or titanium nitride (TiN). The metal 126 may also be deposited or otherwise formed in any suitable manner and may have any suitable thickness(es).

Although FIG. 1 illustrates one example of a Group III-V material-on-silicon device 100 supporting microfluidic cooling using a backside cavity approach, various changes may be made to FIG. 1. For example, the relative sizes, shapes, and dimensions of various components in FIG. 1 may vary from what is shown here and described above. Also, while specific materials or other specific characteristics of the device 100 are provided above, these specific characteristics are examples only, and other embodiments of the device 100 may use any other suitable materials and/or may have any other suitable characteristics.

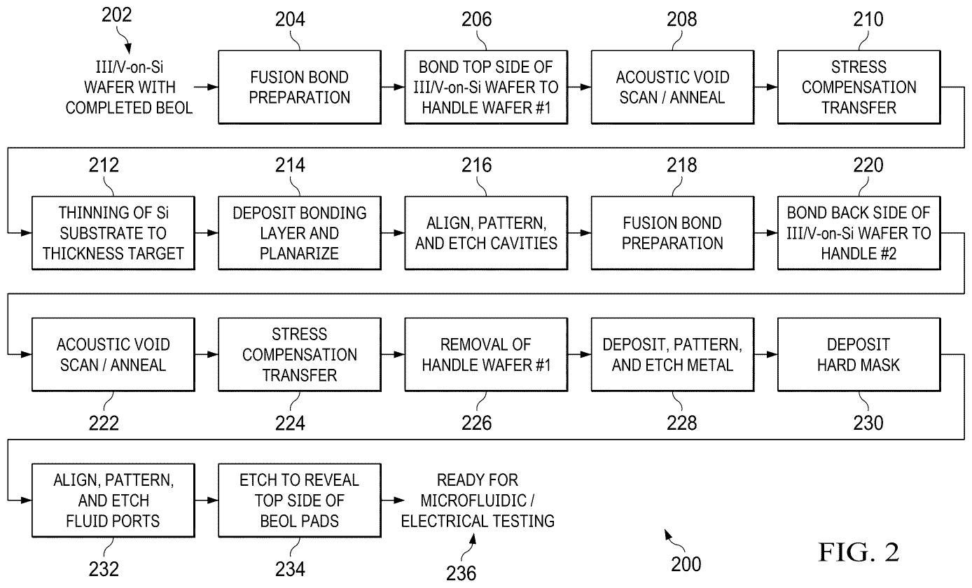

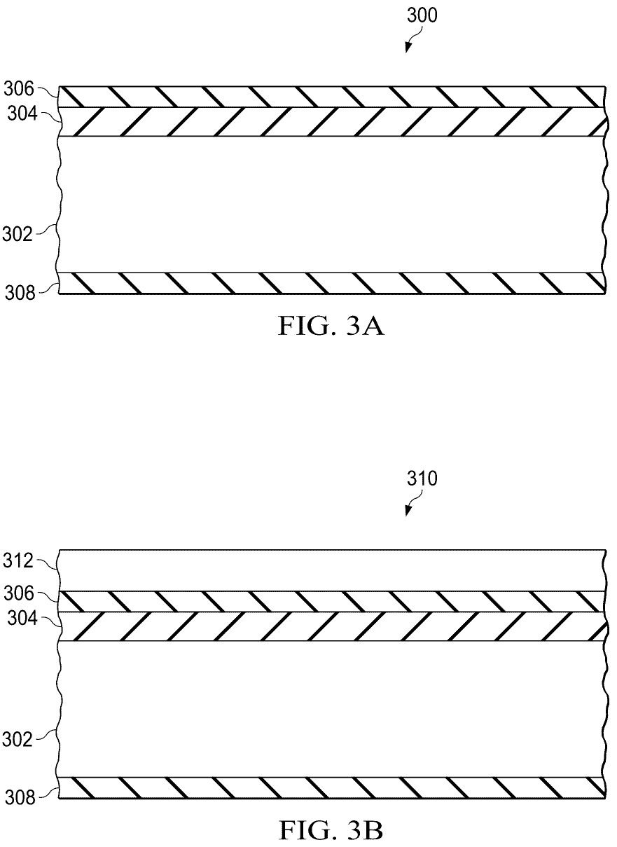

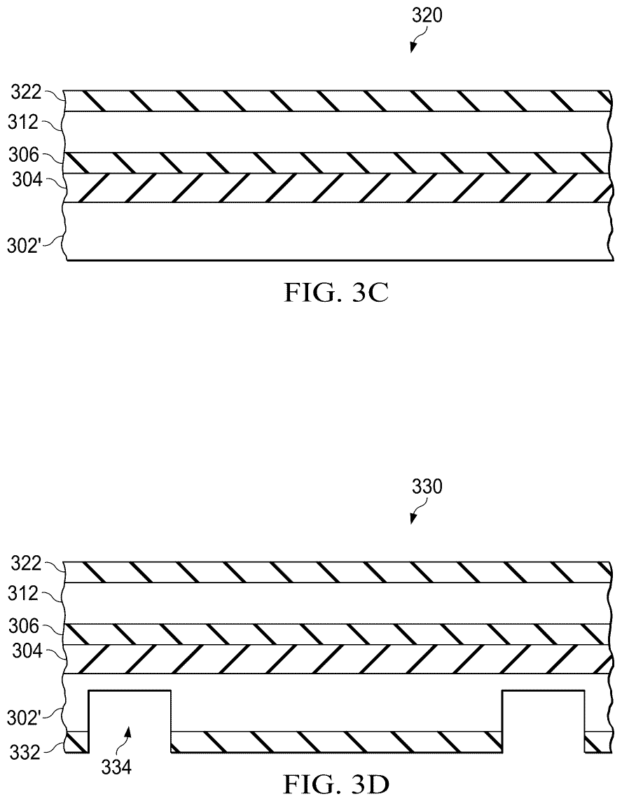

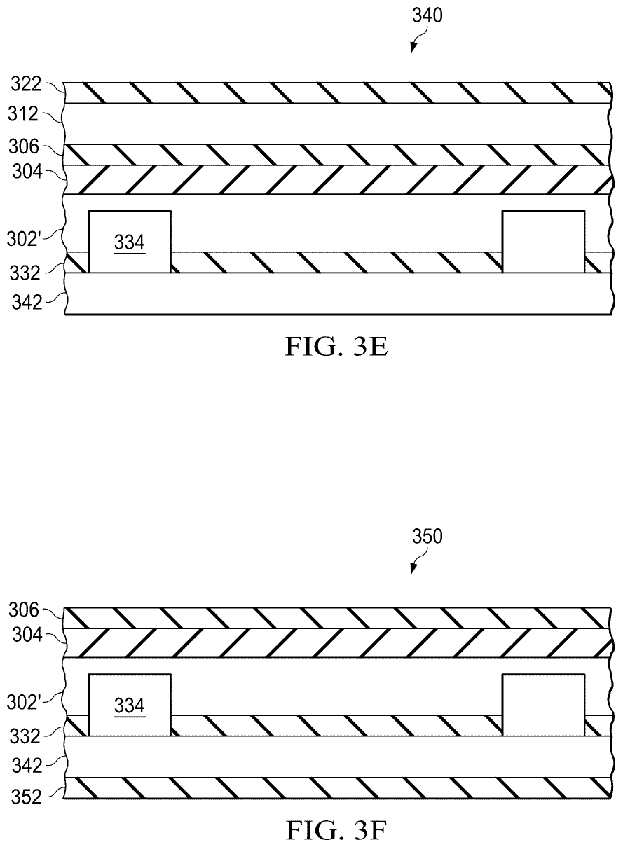

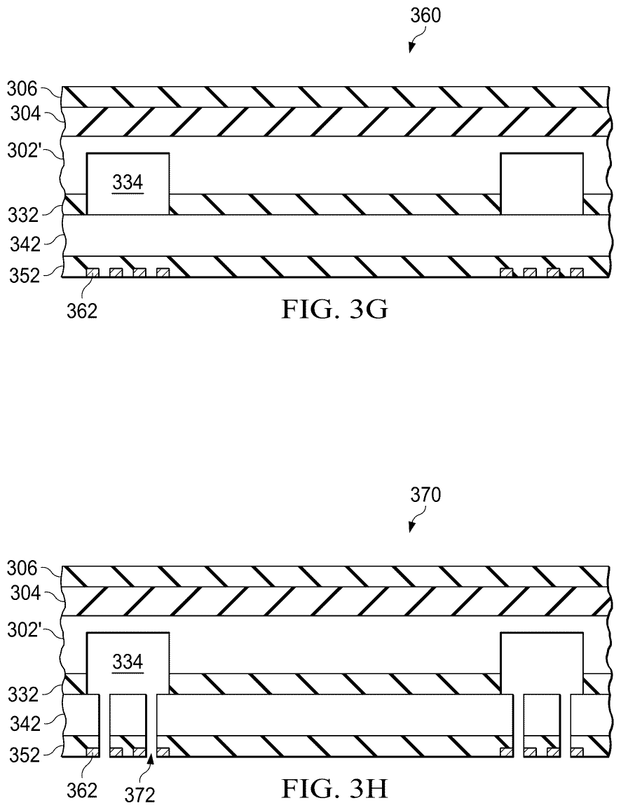

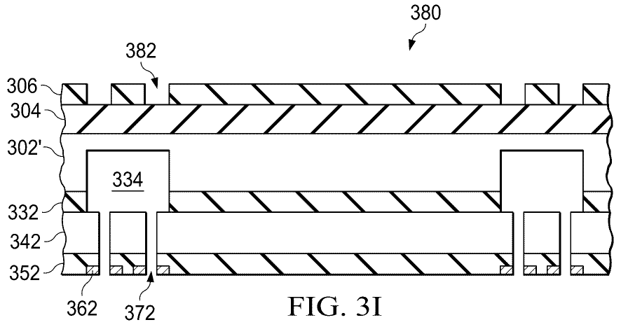

FIG. 2 illustrates an example process 200 for forming a Group III-V material-on-silicon device supporting microfluidic cooling using a backside cavity approach according to this disclosure. The process 200 may, for example, be used to fabricate one or more instances of the Group III-V material-on-silicon device 100 shown in FIG. 1 and described above. FIGS. 3A through 3I illustrate example structures that may be formed during the process 200 of FIG. 2 according to this disclosure. For ease of explanation, the process 200 may often be described below as being used to fabricate gallium nitride-on-silicon devices. However, the same or similar process may be used to form other Group III-V material-on-silicon devices.

As shown in FIG. 2, a Group III-V material-on-silicon (III/V-on-Si) wafer is obtained as an initial step 202. The III/V-on-Si wafer here can have completed its back end of line processing. As an example of this, as shown in FIG. 3A, an initial structure 300 of the III/V-on-Si wafer can include a silicon substrate 302, a Group III-V material and BEOL layer 304, a passivation layer 306, and a back-side stress compensation layer 308. In some embodiments, the silicon substrate 302 represents an <111> silicon substrate. Also, in some embodiments, the Group III-V material and BEOL layer 304 represents a combination of a gallium nitride layer or other Group III-V layer having at least one Group III-V semiconductor device (such as at least one HEMT device) and at least one BEOL layer. The passivation layer 306 may represent an oxide layer, nitride layer, or other layer(s) of material(s) over the Group III-V material and BEOL layer 304. In some cases, the passivation layer 306 may be provided for protection of the underlying Group III-V material and BEOL layer 304.

The back-side stress compensation layer 308 represents at least one layer of material(s) added to the back-side of the silicon substrate 302 in order to counteract stress imparted on the silicon substrate 302 by at least one of the Group III-V material and BEOL layer 304 and the passivation layer 306. For instance, if the Group III-V material and BEOL layer 304 and/or the passivation layer 306 imparts a compressive stress onto the front-side of the silicon substrate 302, the back-side stress compensation layer 308 may be used to impart a corresponding compressive stress onto the back-side of the silicon substrate 302 in order to compensate. If the Group III-V material and BEOL layer 304 and/or the passivation layer 306 imparts a tensile stress onto the front-side of the silicon substrate 302, the back-side stress compensation layer 308 may be used to impart a corresponding tensile stress onto the back-side of the silicon substrate 302 in order to compensate. Various materials and thicknesses of materials are known to impart different types and amounts of stress on the silicon substrate 302, and the exact design of the back-side stress compensation layer 308 can vary depending on the type and amount of stress compensation needed.

A fusion bond preparation operation 204 can be performed using the III/V-on-Si wafer, and a bonding operation 206 can be performed to bond a top side of the III/V-on-Si wafer to a first handle wafer. For example, the fusion bond preparation operation 204 can process the front-side of the III/V-on-Si wafer so that the III/V-on-Si wafer is ready for bonding to the first handle wafer. As a particular example, the passivation layer 306 may undergo a chemical mechanical polishing (CMP) operation or other preparation operation, and the passivation layer 306 may be bonded to the first handle wafer. As an example of this, as shown in FIG. 3B, the fusion bond preparation operation 204 and the bonding operation 206 can result in a structure 310 in which a first handle wafer 312 is bonded or otherwise attached to the passivation layer 306.

An acoustic or other void scan and anneal operation 208, a stress compensation transfer operation 210, and a substrate thinning operation 212 can be performed after the bonding. For example, the acoustic or other void scan and anneal operation 208 can involve performing an acoustic scan or other scan to identify whether there are any voids along the bonding interface between the III/V-on-Si wafer and the first handle wafer, as well as an annealing process to heat and then cool the III/V-on-Si wafer and the first handle wafer. The stress compensation transfer operation 210 can involve the transfer of stress compensation from the back-side of the structure to the front-side of the structure. The substrate thinning operation 212 can involve a grinding operation, CMP operation, or other operation that removes a portion of the silicon substrate 302.

As an example of this, as shown in FIG. 3C, these operations 208-212 can result in a structure 320 in which (i) the back-side stress compensation layer 308 has been removed and a front-side stress compensation layer 322 has been formed on the first handle wafer 312 and (ii) the silicon substrate 302 has been thinned to form a silicon substrate 302′. The front-side stress compensation layer 322 represents at least one layer of material(s) added to the front-side of the structure 320 in order to counteract stress imparted on other portions of the structure 320. Again, various materials and thicknesses of materials are known to impart different types and amounts of stress on a semiconductor structure, and the exact design of the front-side stress compensation layer 322 can vary depending on the type and amount of stress compensation needed.

A bonding layer can be formed and planarized during a formation operation 214, and an align/pattern/etch operation 216 can be performed to form one or more cavities in the thinned silicon substrate. For example, the formation operation 214 may include depositing or otherwise forming an oxide, nitride, or other bonding layer on the back-side of the thinned silicon substrate. The align/pattern/etch operation 216 may include using a mask or other technique to form one or more cavities in the thinned silicon substrate by etching through the bonding layer and into the thinned silicon substrate. As an example of this, as shown in FIG. 3D, these operations 214-216 can result in a structure 330 in which (i) a bonding layer 332 is formed on the back-side of the thinned silicon substrate 302′ and (ii) one or more cavities 334 are formed by etching through the bonding layer 332 and into the thinned silicon substrate 302′. Note that the one or more cavities 334 may be formed to any suitable depth(s) within the thinned silicon substrate 302′. In some cases, the one or more cavities 334 may extend almost all the way through the thinned silicon substrate 302′, thereby allowing the one or more cavities 334 to be formed very close to one or more regions of the Group III-V material and BEOL layer 304.

Another fusion bond preparation operation 218 can be performed, and a bonding operation 220 can be performed to bond a back-side of the III/V-on-Si wafer to a second handle wafer. For example, the fusion bond preparation operation 218 can process the back-side of the bonding layer 332 so that the bonding layer 332 is ready for bonding to the second handle wafer. As a particular example, the bonding layer 332 may undergo a CMP operation or other preparation operation, and the bonding layer 332 may be bonded to the second handle wafer. As an example of this, as shown in FIG. 3E, these operations 218-220 can result in a structure 340 in which a second handle wafer 342 is attached to the thinned silicon substrate 302′ by the bonding layer 332.

Another acoustic or other void scan and anneal operation 222, a stress compensation transfer operation 224, and a handle wafer removal operation 226 can be performed after the second bonding. For example, the acoustic or other void scan and anneal operation 222 can involve performing an acoustic or other scan to identify whether there are any voids along the bonding interface between the bonding layer and the second handle wafer, as well as an annealing process to heat and then cool the bonding layer and the second handle wafer. The stress compensation transfer operation 224 can involve the transfer of stress compensation from the front-side of the structure to the back-side of the structure. The handle wafer removal operation 226 can involve a grinding operation, CMP operation, or other operation that removes the first handle wafer.

As an example of this, as shown in FIG. 3F, these operations 222-226 can result in a structure 350 in which (i) the first handle wafer 312 and the front-side stress compensation layer 322 have been removed and (ii) a back-side stress compensation layer 352 has been formed on the second handle wafer 342. The back-side stress compensation layer 352 represents at least one layer of material(s) added to the back-side of the structure 350 in order to counteract stress imparted on other portions of the structure 350. Again, various materials and thicknesses of materials are known to impart different types and amounts of stress on a semiconductor structure, and the exact design of the back-side stress compensation layer 352 can vary depending on the type and amount of stress compensation needed.

A metal deposition/pattern/etching operation 228 may optionally be used to etch the back-side stress compensation layer and deposit metal into etched portions of the back-side stress compensation layer. For example, the deposition/pattern/etching operation 228 may be used to etch the back-side stress compensation layer in one or more areas where one or more fluid ports will be formed in order to support or improve the formation of seal(s) between the fluid port(s) and one or more external fluid pathways. As an example of this, as shown in FIG. 3G, the operation 228 can result in a structure 360 in which the back-side stress compensation layer 352 has been etched and metal 362 has been deposited into the etched portions of the back-side stress compensation layer 352.

A hard mask deposition operation 230 can be performed to form a hard mask over the back-side stress compensation layer, and an align/pattern/etch operation 232 can be performed to form one or more fluid ports through the second handle wafer and in fluid communication with each cavity. For example, the hard mask deposition operation 230 may form a mask over the back-side stress compensation layer so that only areas of the back-side stress compensation layer to be etched are exposed. The align/pattern/etch operation 232 may include etching through the back-side stress compensation layer and the second handle wafer until pathways are formed to the previously-formed cavity or cavities in the second handle wafer. As an example of this, as shown in FIG. 3H, the operations 230-232 can result in a structure 370 in which one or more fluid ports 372 are formed through the back-side stress compensation layer 352 and into the second handle wafer 342. Each cavity 334 here may be in fluid communication with at least one fluid port 372.

An etching operation 234 can be performed to expose electrical pads or other electrical connections of the BEOL layer. For example, the etching operation 234 may involve patterning a mask over the passivation layer and etching through portions of the passivation layer to expose electrical pads or other electrical connections of the Group III-V material and BEOL layer. As an example of this, as shown in FIG. 3I, the operation 234 can result in a structure 380 in which one or more openings 382 are formed through the passivation layer 306 to the Group III-V material and BEOL layer 304. Each opening 382 can be used to expose one or more electrically-conductive pads or other conductive structures of the Group III-V material and BEOL layer 304. At this point, the resulting structure 380 can be made available during a final step 236 for microfluidic, electrical, or other testing and for further use, such as during fabrication of a larger structure.

The process 200 described above can provide various benefits or advantages depending on the implementation. For example, the process 200 can be used to create cooling channels in III/V-on-Si wafers or other Group III-V material-on-silicon devices while accounting for the inherent fragility of epitaxial gallium nitride or other Group III-V materials deposited onto silicon substrates. The process 200 supports processing on both sides of a structure and provides for the use of various stress compensation layers to compensate for and transfer stresses during the overall fabrication process, thereby providing effective stress management. The process 200 supports the use of oxide or other bonding operations, as well as cavity and fluid port formation operations, that effectively allow for the creation of microfluidic cooling channels even in the presence of fragile semiconductor structures. The process 200 supports the bonding of thin or handle wafers that include silicon and the effective alignment of components on the front and back sides of the structure. Overall, the process 200 provides an effective technique for forming cooling channels in gallium nitride or other Group III-V material-on-silicon devices.

Although FIG. 2 illustrates one example of a process 200 for forming a Group III-V material-on-silicon device supporting microfluidic cooling using a backside cavity approach, various changes may be made to FIG. 2. For example, while certain operations may be shown as being used to fabricate certain components of a Group III-V material-on-silicon device, other or additional operations may be used to form the same or similar components. Although FIGS. 3A through 3I illustrate examples of structures that may be formed during the process 200 of FIG. 2, various changes may be made to FIGS. 3A through 3I. For instance, the relative sizes, shapes, and dimensions of various components in FIGS. 3A through 3I may vary from what is shown here and described above. Also, while specific materials or other specific characteristics of the components of the Group III-V material-on-silicon device are provided above, these specific characteristics are examples only, and other embodiments of the Group III-V material-on-silicon device may use any other suitable materials and/or may have any other suitable characteristics.

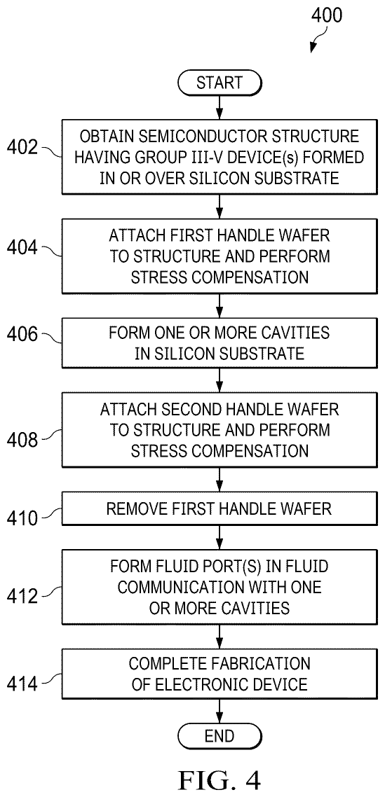

FIG. 4 illustrates an example method 400 for forming a Group III-V material-on-silicon device supporting microfluidic cooling using a backside cavity approach according to this disclosure. The method 400 may, for example, be used to fabricate one or more instances of the Group III-V material-on-silicon device 100 shown in FIG. 1 and described above. However, the method 400 may be used to form any suitable Group III-V material-on-silicon device(s) designed in accordance with this disclosure.

As shown in FIG. 4, a semiconductor structure having one or more Group III-V devices formed in or over a silicon substrate is obtained at step 402. This may include, for example, fabricating or otherwise obtaining a III/V-on-Si wafer having an initial structure 300 with a silicon substrate 302, a Group III-V material and BEOL layer 304, a passivation layer 306, and a back-side stress compensation layer 308. A first handle wafer is attached to the structure and stress compensation is performed at step 404. This may include, for example, bonding or otherwise attaching the first handle wafer 312 to the structure, removing the back-side stress compensation layer 308, and forming the front-side stress compensation layer 322.

One or more cavities are formed in the silicon substrate of the semiconductor structure at step 406. This may include, for example, thinning the silicon substrate 302 (if needed), forming the bonding layer 332 on the back-side of the silicon substrate 302 or thinned silicon substrate 302′, and etching one or more cavities 334 through the bonding layer 332 and into the silicon substrate 302 or thinned silicon substrate 302′. In some cases, the one or more cavities 334 may be etched almost completely through the silicon substrate 302 or thinned silicon substrate 302′. A second handle wafer is attached to the structure and stress compensation is performed at step 408. This may include, for example, bonding or otherwise attaching the second handle wafer 342 to the structure, removing the front-side stress compensation layer 322, and forming the back-side stress compensation layer 352. The first handle wafer is removed at step 410. This may include, for example, removing the first handle wafer 312 from the structure.

One or more fluid ports in fluid communication with each of the one or more cavities are formed at step 412. This may include, for example, etching through one or more areas of the back-side stress compensation layer 352 and into the silicon substrate 302 or thinned silicon substrate 302′ to form one or more fluid ports 372. Note that (if desired) metal 362 may be deposited around each area where a fluid port 372 is being formed to facilitate more effective sealing of the fluid port(s) 372. The one or more cavities 334 and the one or more fluid ports 372 represent one or more cooling channels formed in the structure. Fabrication of an electronic device can be completed at step 414. This may include, for example, etching through the passivation layer 306, testing the resulting structure, and performing additional operations to form electrical connections to the Group III-V material and BEOL layer 304.

Although FIG. 4 illustrates one example of a method 400 for forming a Group III-V material-on-silicon device supporting microfluidic cooling using a backside cavity approach, various changes may be made to FIG. 4. For example, while shown as a series of steps, various steps in FIG. 4 may overlap, occur in parallel, occur in a different order, be combined, be sub-divided, or occur any number of times.

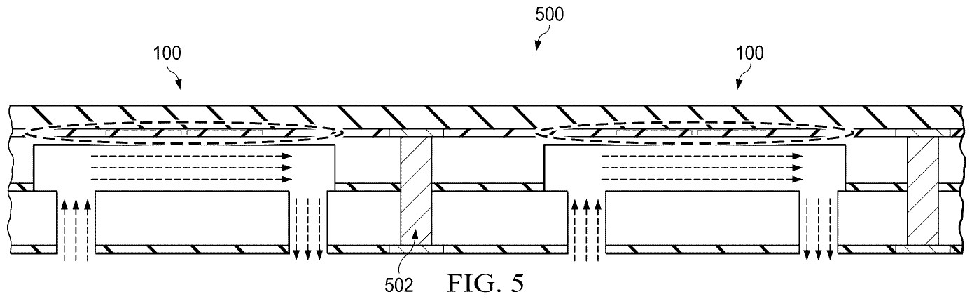

FIGS. 5 through 7 illustrate example structures that integrate Group III-V material-on-silicon devices supporting microfluidic cooling using a backside cavity approach according to this disclosure. For example, these structures represent portions of electronic devices that may be fabricated using one or more instances of the Group III-V material-on-silicon device 100 described above. The one or more instances of the Group III-V material-on-silicon device 100 in each of these structures may be fabricated using the process 200 described above.

As shown in FIG. 5, a structure 500 can include one or more instances of the Group III-V material-on-silicon device 100. The structure 500 can also include one or more conductive vias 502 that extend partially into or completely through the structure 500. The one or more conductive vias 502 may be used to transport one or more electrical signals or power into or through the structure 500. Also, in some cases, multiple instances of the structure 500 can be stacked, and the one or more vias 502 may be used to transport one or more electrical signals or power partially into or completely through the stacked structures 500. Each conductive via 502 may be formed using any suitable material(s), such as copper or other metal(s). Each conductive via 502 may also be formed in any suitable manner. In some embodiments, each conductive via 502 may represent a through silicon via (TSV).

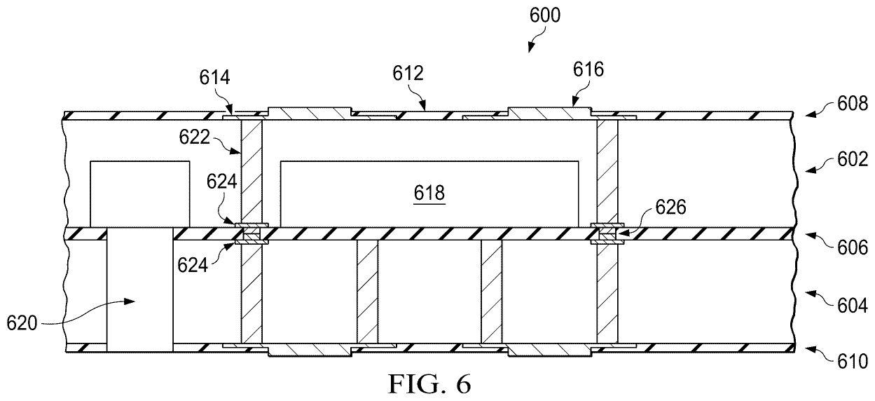

As shown in FIG. 6, a structure 600 can represent a thermal interposer that includes two silicon substrates 602 and 604, such as two substrates formed using high-resistivity silicon (HRS). The silicon substrates 602-604 can be attached to one another using an oxide layer or other bonding layer 606. An upper layer 608 and a lower layer 610 may each include one or more layers of material(s) in or on which circuit components may be fabricated. In some cases, for instance, the layers 608-610 may be formed using benzocyclobutene (BCB). In the illustrated example, each layer 608-610 can include one or more solder masks 612, one or more redistribution layers 614, and under-bump metal 616. In particular embodiments, the one or more redistribution layers 614 may be formed using copper, and the under-bump metal 616 may be formed using copper or electroless nickel immersion gold (ENIG). In the following discussion, it is assumed that one or more of the circuit components in the layer 608 represent one or more Group III-V semiconductor devices to be cooled.

At least one cavity 618 and one or more fluid ports 620 can be formed in the structure 600 using the techniques described above. This leads to the creation of one or more cooling channels in the structure 600. Also, one or more conductive vias 622 can be formed through the silicon substrates 602-604, such as to electrically connect various circuit components in the layers 608-610. In some cases, for instance, each conductive via 622 may represent a copper-filled through silicon via or other conductive structure. Different conductive vias 622 through different silicon substrates 602-604 may be electrically connected to each other in any suitable manner. In this example, different conductive vias 622 are electrically connected to different redistribution layers 622, and the redistribution layers 622 are electrically connected to each other using hybrid posts 624. The redistribution layers 622 and hybrid posts 624 may be formed using any suitable conductive material(s), such as copper or one or more metals, and in any suitable manner. Note, however, that the redistribution layers 622 may be electrically connected in any other suitable manner.

As can be seen in FIG. 6, the structure 600 supports electrical connection between circuit components on top and bottom of the structure 600. The structure 600 also includes an integrated cooling mechanism within one or both of the substrates 602-604, thereby providing cooling for one or more of the circuit components. In this specific example, for instance, the layer 608 may include one or more Group III-V semiconductor devices or other circuit components to be cooled, and the cavity 618 can be formed relatively close to that region of the layer 608.

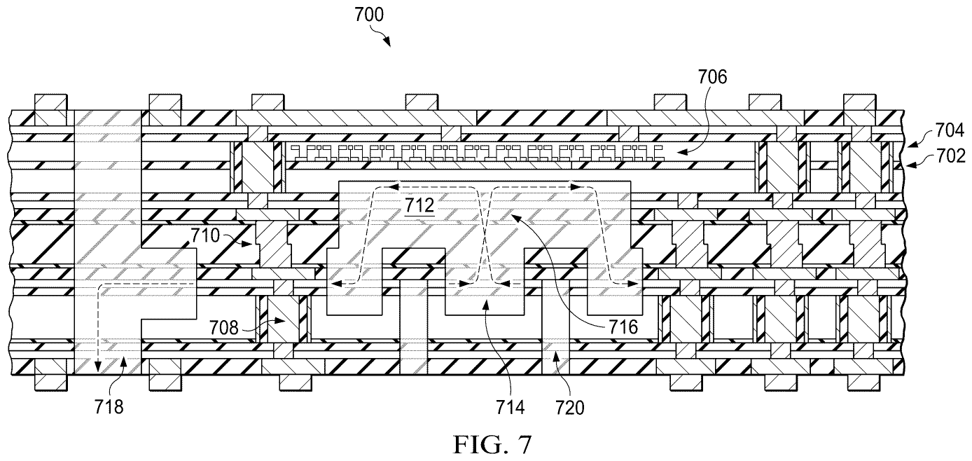

It is possible to design and fabricate a large number of structures having any arbitrary complexity while supporting microfluidic cooling using the described techniques. For example, as can be seen in FIG. 7, a multi-layer structure 700 can include a Group III-V layer 702 and a BEOL layer 704 (among a large number of other layers). The BEOL layer 704 includes conductive pads 706 that, as noted above, can be exposed and used to form electrical connections with circuit components in the Group III-V layer 702. Conductive vias 708 (such as TSVs) can be used to transport electrical signals or power partially into or completely through the structure 700. In this example, various vias 708 can be electrically coupled to each other using DBH bonds 710 or other suitable connections.

At least one cavity 712 can be formed within the structure 700 near the Group III-V layer 702. In this example, a manifold 714 can act as one fluid port to provide a cooling fluid into the cavity 712. A flow of the cooling fluid can be split in a region 716 of the structure 700 and directed in opposite directions through the cavity 712. Fluid ports 718 (such as those on opposite sides of the cavity 712) can be used to allow the cooling fluid to exit the structure 700. One or more air gaps 720 may optionally be used to allow rejection of some thermal energy into the ambient environment.

Although FIGS. 5 through 7 illustrate examples of structures that integrate Group III-V material-on-silicon devices supporting microfluidic cooling using a backside cavity approach, various changes may be made to FIGS. 5 through 7. For example, as can be seen here, there are a variety of ways in which one or more Group III-V material-on-silicon devices 100 may be used. However, these example structures are for illustration only, and FIGS. 5 through 7 do not limit the scope of this disclosure to these specific use cases or applications.

In some embodiments, various functions described in this patent document are implemented or supported by a computer program that is formed from computer readable program code and that is embodied in a computer readable medium. The phrase “computer readable program code” includes any type of computer code, including source code, object code, and executable code. The phrase “computer readable medium” includes any type of medium capable of being accessed by a computer, such as read only memory (ROM), random access memory (RAM), a hard disk drive, a compact disc (CD), a digital video disc (DVD), or any other type of memory. A “non-transitory” computer readable medium excludes wired, wireless, optical, or other communication links that transport transitory electrical or other signals. A non-transitory computer readable medium includes media where data can be permanently stored and media where data can be stored and later overwritten, such as a rewritable optical disc or an erasable memory device.

It may be advantageous to set forth definitions of certain words and phrases used throughout this patent document. The terms “application” and “program” refer to one or more computer programs, software components, sets of instructions, procedures, functions, objects, classes, instances, related data, or a portion thereof adapted for implementation in a suitable computer code (including source code, object code, or executable code). The term “communicate,” as well as derivatives thereof, encompasses both direct and indirect communication. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. An apparatus comprising:
a silicon substrate;
a Group III-V layer over a front-side of the silicon substrate, the Group III-V layer comprising at least one Group III-V material and one or more circuit components; and
a silicon wafer attached to a back-side of the silicon substrate;
wherein the silicon substrate comprises a cavity formed in the back-side of the silicon substrate, the cavity extending partially through the silicon substrate and adjacent to a region of the Group III-V layer containing at least one of the one or more circuit components;
wherein the silicon wafer comprises one or more fluid ports in fluid communication with the cavity; and
wherein the cavity and the one or more fluid ports form a cooling channel configured to provide a flow of cooling fluid through the silicon wafer and the silicon substrate.

2. The apparatus of claim 1, further comprising:
a back end of line (BEOL) layer over the Group III-V layer, the BEOL layer providing electrical connection to the one or more circuit components.

3. The apparatus of claim 1, further comprising:
a bonding layer configured to attach the silicon wafer to the silicon substrate.

4. The apparatus of claim 1, further comprising:
a dielectric layer over a back-side of the silicon wafer.

5. The apparatus of claim 1, further comprising:
a metal deposited around each opening of the one or more fluid ports.

6. The apparatus of claim 1, further comprising:
one or more conductive vias extending at least partially through the silicon substrate and the silicon wafer.

7. The apparatus of claim 6, wherein at least one via in the silicon substrate is electrically connected to at least one via in the silicon wafer.

8. The apparatus of claim 1, wherein the silicon substrate, the Group III-V layer, and the silicon wafer form one layer of a multi-layer structure.

9. The apparatus of claim 1, wherein the at least one Group III-V material comprises gallium nitride.

10. A method comprising:
obtaining a semiconductor structure comprising a silicon substrate and a Group III-V layer over a front-side of the silicon substrate, the Group III-V layer comprising at least one Group III-V material and one or more circuit components;
forming a cavity in a back-side of the silicon substrate, the cavity extending partially through the silicon substrate and adjacent to a region of the Group III-V layer containing at least one of the one or more circuit components;
attaching a silicon wafer to the back-side of the silicon substrate; and
forming one or more fluid ports through the silicon wafer and in fluid communication with the cavity;
wherein the cavity and the one or more fluid ports form a cooling channel configured to provide a flow of cooling fluid through the silicon wafer and the silicon substrate.

11. The method of claim 10, wherein:
the semiconductor structure further comprises a first back-side stress compensation layer over the back-side of the silicon substrate; and
the method further comprises, prior to forming the cavity in the back-side of the silicon substrate:
attaching an additional silicon wafer to a passivation layer over the front-side of the silicon substrate;
removing the first back-side stress compensation layer; and
forming a front-side stress compensation layer over the additional silicon wafer.

12. The method of claim 11, wherein the method further comprises, after forming the cavity in the back-side of the silicon substrate:
removing the front-side stress compensation layer; and
forming a second back-side stress compensation layer over a back-side of the silicon wafer; and
wherein each fluid port is formed through the second back-side stress compensation layer.

13. The method of claim 10, wherein:
the semiconductor structure further comprises a back end of line (BEOL) layer over the Group III-V layer, the BEOL layer providing electrical connection to the one or more circuit components; and
the method further comprises, after forming the one or more fluid ports through the silicon wafer, etching the BEOL layer to expose conductive pads of the BEOL layer.

14. The method of claim 10, wherein attaching the silicon wafer to the back-side of the silicon substrate comprises using a bonding layer to attach the silicon wafer to the silicon substrate.

15. The method of claim 10, further comprising:
depositing a metal around each opening of the one or more fluid ports.

16. The method of claim 10, further comprising:
forming one or more conductive vias extending at least partially through the silicon substrate and the silicon wafer.

17. The method of claim 10, wherein the at least one Group III-V material comprises gallium nitride.

18. A method comprising:
obtaining an electronic device comprising:
a silicon substrate;
a Group III-V layer over a front-side of the silicon substrate, the Group III-V layer comprising at least one Group III-V material and one or more circuit components; and
a silicon wafer attached to a back-side of the silicon substrate;
wherein the silicon substrate comprises a cavity formed in the back-side of the silicon substrate, the cavity extending partially through the silicon substrate and adjacent to a region of the Group III-V layer containing at least one of the one or more circuit components; and
wherein the silicon wafer comprises one or more fluid ports in fluid communication with the cavity; and
passing a cooling fluid through the one or more fluid ports into and out of the cavity.

19. The method of claim 18, wherein the one or more circuit components comprise at least one high-electron-mobility transistor.

20. The method of claim 18, wherein the at least one Group III-V material comprises gallium nitride.
